(19) United States
(12) Patent Application Publication
(10) Pub. No.: US 2024/0232476 A1
(43) Pub. Date: Jul. 11, 2024

(54) SIMULATION TEST VALIDATION

(71) Applicant: GM Cruise Holdings LLC, San Francisco, CA (US)

(72) Inventors: Hariprasad Govardhanam, Fremont, CA (US); Luke Murchison, Belmont, CA (US)

(21) Appl. No.: 18/093,666

(22) Filed: Jan. 5, 2023

(51) Int. Cl. G06F 30/27; G06F 30/15

(52) U.S. Cl. CPC G06F 30/27; G06F 30/15

(57) ABSTRACT

The subject technology provides solutions for evaluating AV performance in simulated test environments. In some aspects, the disclosed technology includes a process for receiving road data comprising autonomous vehicle (AV) sensor data, generating simulation (SIM) data based on the road data, and measuring one or more first performance metrics, wherein the one or more first performance metrics correspond with a performance of an AV in the real-world environment. The process can further include steps for measuring one or more second performance metrics, wherein the one or more second performance metrics correspond with a performance of the AV in the simulated environment, training a machine-learning (ML) model to predict a correspondence between the performance of the AV in the real-world environment and the performance of the AV in the simulated environment. Systems and machine-readable media are also provided.

### BACKGROUND

### 1. Technical Field

The subject technology generally provides solutions for improving autonomous vehicle (AV) tests and in particular, for evaluating AV performance in simulated test environments against AV performance in real-world environments.

### 2. Introduction

Autonomous vehicles (AVs) are vehicles having computers and control systems that perform driving and navigation tasks conventionally performed by a human driver. As AV technologies continue to advance, they will be increasingly used to improve transportation efficiency and safety. As such, AVs will need to perform many of the functions that are conventionally performed by human drivers, such as performing navigation and routing tasks necessary to provide safe and efficient transportation. Such tasks may require the collection and processing of large quantities of data using various sensor types, including but not limited to cameras, Light Detection and Ranging (LiDAR) sensors, and/or Radio Detection and Ranging (RADAR) disposed on the AV. In some instances, the collected data can be used to generate (or render) simulated (or synthetic/virtual) environments that can be used to perform additional AV testing and training.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates a conceptual block diagram of an example system that can be used to compare autonomous vehicle (AV) performance metrics for AV performance in a real-world environment against AV performance in a synthetic (virtual) environment, according to some aspects of the disclosed technology.

FIG. 2 illustrates a conceptual block diagram of an example system for training a machine-learning (ML) model to predict AV performance, according to some aspects of the disclosed technology.

FIG. 3 illustrates a conceptual block diagram of an example system for implementing a machine-learning (ML) model to predict AV performance, according to some aspects of the disclosed technology.

FIG. 4 illustrates steps of an example process for training a machine-learning (ML) model to make AV performance predictions, according to some aspects of the disclosed technology.

FIG. 5 conceptually illustrates a simulation generation process, according to some aspects of the disclosed technology.

FIG. 6 illustrates an example system environment that can be used to facilitate AV dispatch and operations, according to some aspects of the disclosed technology.

FIG. 7 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring the concepts of the subject technology.

Some aspects of the present technology may relate to the gathering and use of data available from various sources to improve safety, quality, and experience. The present disclosure contemplates that in some instances, this gathered data may include personal information. The present disclosure contemplates that the entities involved with such personal information respect and value privacy policies and practices.

One barrier to improving the safety and performance of autonomous vehicles (AVs) is acquiring enough training data to adequately train and optimize various machine-learning models in the AV software stack. For example, large quantities of data are typically needed to refine machine-learning (ML) models used to implement perception, prediction, planning and/or control layers of the AV software stack. One approach that can be used to augment the corpus of available training data is to simulate AV operations in a simulated (or virtual) environment, for example, that emulates environments or driving scenarios that AVs are likely to encounter when operating in the real-world. However, training and testing performed in the simulated environment is typically most useful when the simulated environment (also referred to herein as SIM environment) accurately represents characteristics of the real-world, such as through the accurate representation of objects, entities in the scene (e.g., other vehicles, pedestrians, etc.), and/or interactions between various objects and entities that result in various driving scenarios that may be encountered by the AV.

Performing AV testing and training in a SIM environment can be extremely complex and it is often difficult for human operators to easily intuit the enumerate ways in which the SIM environments may deviate or differ from the real-world scenarios they represent (also referred to herein as divergence, or SIM divergence). For example, real-world objects (e.g., roadways, buildings, or other vehicles) and/or AV systems (e.g., AV sensors, and/or compute characteristics), may be imprecisely modeled in the SIM environment, resulting in simulated scenarios that are lacking in critical aspects or characteristics, but which are difficult to identify by human operators, such as AV engineers.

To improve the fidelity of SIM environments, many such environments are generated (or seeded) using real-world data (e.g., road-data) that includes data captured from physical AV sensors during operation in the real-world. As such, road-data can include various types of sensor data, including but not limited to Light Detection and Ranging (LiDAR) data, Radio Detection and Ranging (RADAR) data, time-of-flight (ToF) sensors, camera (image) data, and the like. Additionally, road-data can include other types of data, including but not limited to map data, and/or metadata regarding various systems, system states, and/or environmental factors that were observed or encountered by the physical AV while operating in the real-world. However, it would be advantageous to enable the creation of high-fidelity SIM environments that are entirely generated and not based on physical sensor data, i.e., road-data collected from operating AVs.

Aspects of the disclosed technology provide solutions for identifying divergences (or gaps) between real-world and SIM environments by predicting AV performance in a SIM environment as compared with the real-world environment that the SIM environment represents. By conveniently comparing AV performance, between SIM and real-world environments, human operators may more easily understand and identify potential causes of simulation divergence. As discussed in further detail below, AV performance may be evaluated across several performance metrics, including but not limited to a safety metric (or safety score), a comfort metric (or comfort score) and/or AV kinematic characteristics, including but not limited to AV trajectory, pose, acceleration, and/or velocity, etc. Additionally, in some implementations, performance metrics may be evaluated for different AV operating domains, for example, performance metrics may be differently evaluated under different weather conditions, road conditions, AV use cases (e.g., passenger delivery or freight shipping), etc.

Comparative predictions of AV performance may be performed using a machine-learning (ML) model, for example that has been trained to provide/output performance correspondence metrics on a quantitative scale. For example, a ML model may be configured to predict a correspondence between AV performance in a SIM environment as compared to AV performance in a real-world environment on a quantitative interval, such as an interval of [−1, 1], whereby a score of −1 can indicate that AV performance in SIM is predicted to be much lower/worse than AV performance in the corresponding real-world environment. Similarly, an output of 1 can indicate that AV performance in the SIM environment is predicted to be much better than AV performance in the corresponding real-world environment; an output of 0 can indicate a perfect correspondence between AV performance in the SIM environment and AV performance in the real-world environment.

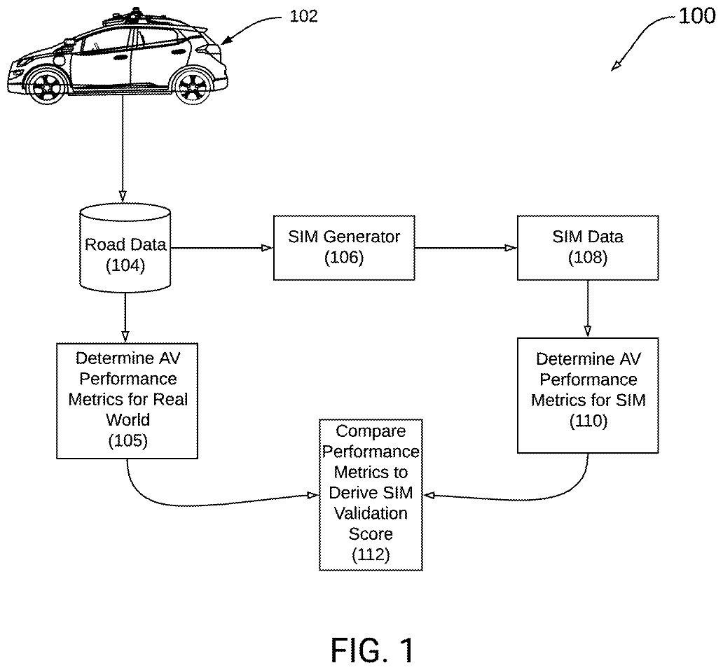

Depending on the desired implementation, performance correspondence metrics can be generated for a given type of AV performance metric and/or as an aggregate scoring across two or more AV performance metrics. By way of example, the ML model may be configured to predict a correspondence between the performance of the AV in the real-world environment and the performance of the AV in the simulated environment with respect to a safety score. In such instances, a score of 1, e.g., on the interval [−1, 1], can indicate that AV safety metrics are predicted to be much higher/greater for AV performance in the SIM environment as compared to the real-world environment. In relation to comfort scoring, an output of −1 by the ML model may indicate that AV comfort performance in the SIM environment is predicted to be worse (e.g., less comfortable) than AV performance in a corresponding real-world environment. Further details regarding the calculation/determination of comparative performance metrics are provided with respect to FIG. 1, below.

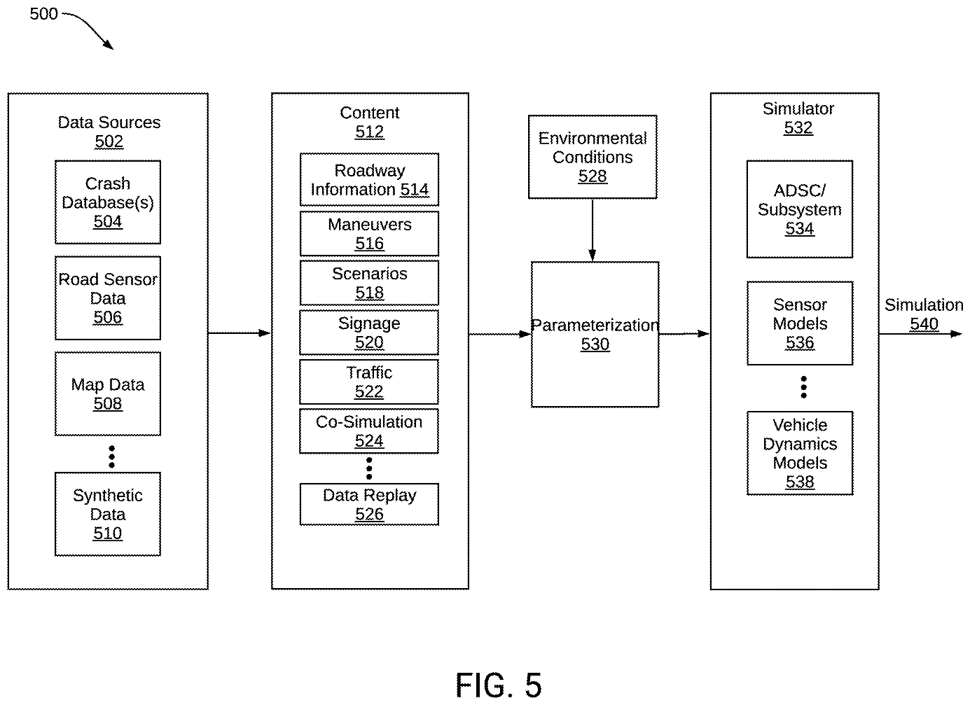

FIG. 1 illustrates an example system that can be used to compare AV performance metrics as between a real-world environment and a simulated (or synthetic) environment. As discussed above, simulated/synthetic environments can be generated (or seeded) from real-world sensor data, such as LiDAR, RADAR, Time-of Flight (ToF) sensor, and/or camera data, etc., collected by mounted sensors on an AV 102. Collected sensor data, among other types of metadata, are represented in road data 104, which can be provided to a simulation (SIM) generator 106 and used to produce SIM data 108. The SIM generator 106 can include a variety of data preparation and parameterization processes and may include the receipt/generation of other types of data useful for generating a simulated environment (such as atmospheric effects) in which operations of AV 102 may be simulated. Further details regarding SIM generator 106 are provided with respect to FIG. 5, below.

In some aspects, SIM data 108 can be used to generate a simulated environment that can be used to train and/or test various AV systems/features, e.g., through the simulated/virtual operation of AV 102 in the simulated environment. By running tests/simulations in the simulated environment, AV performance metrics for AV operation in the simulated environment can be determined/calculated (block 110). Separately, and in some instances concurrently, similar AV performance metrics can be determined/calculated for performance of AV 102 in the corresponding real-world environment (block 105). For example, performance metrics can be used to quantitatively (or qualitatively) score the performance of AV 102 on various factors such as safety, comfort, operating cost, legal and/or regulatory compliance, and/or efficiency, etc. Additionally, performance metrics may be used to compare AV behaviors and/or kinematics for operation in the real-world and SIM environments. By way of example, performance metrics may be used to compare AV trajectories, acceleration, and/or velocity at different times during operation in the real-world and/or SIM environments.

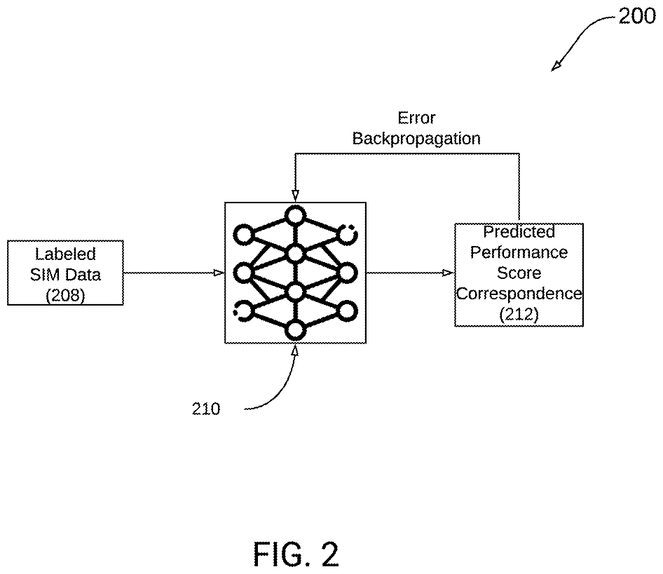

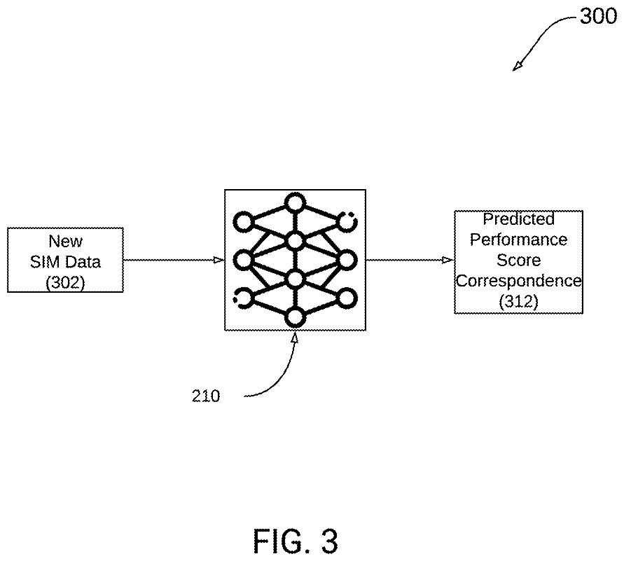

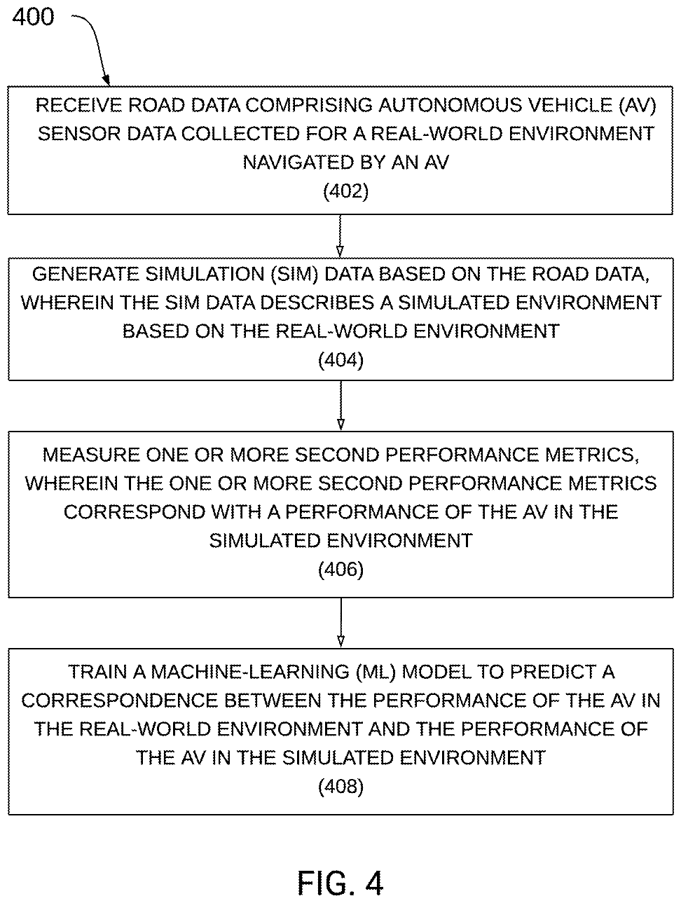

Once AV performance metrics have been determined/calculated for operation of AV 102 in the real-world and simulated environment, the respective performance metrics can be compared (block 112) to determine/derive a SIM validation score. As discussed above, the SIM validation score (also referred to herein as a correspondence score) can be a quantitative score, for example, on the interval [−1, 1], where a score of −1 indicates that AV performance in the simulated environment is lower/worse than performance in the real-world environment. A score of 0 can indicate a perfect (or near perfect) correspondence between AV performance in the SIM environment and AV performance in the real-world environment, and a score of 1 can indicate that AV performance in the SIM environment is greater/better than AV performance in the real-world environment. As discussed in further detail below with respect to FIG. 2, a machine-learning (ML) model can be trained to predict correspondence between AV performance scores in a SIM environment and a corresponding real-world environment. Additionally, in some aspects, as discussed in further detail with respect to FIGS. 3 and 4, the ML model, once trained, can be extended to make SIM performance score estimates/predictions based on only SIM input data, e.g., without the need for a corresponding real-world, for example, as represented by AV road data.

FIG. 2 illustrates a conceptual block diagram of an example system 200 for training a machine-learning (ML) model 210 to predict AV an AV performance correspondence score. Generally, training of ML model 210 can be performed by exposing ML model 210 to a large number of equivalent synthetic and real-world scenarios and then measuring the divergences between them along with the performance metrics. The measured divergences can then be used as the inputs to model 210 and the performance metrics can be used to generate training labels (or ground-truth training labels), that can be used to train model 210. In some instances, a cross-validation methodology can be used to train model 210 on different subsets of data to get the best possible model. Depending on the desired implementation, ML model 210 may be a regression model, a random forest, or a neural network (e.g., a deep-learning neural network). It is understood that other types of ML architectures may be implemented, without departing from the scope of the disclosed technology.

In operation, ML model 210 can be configured to receive labeled SIM data 208, for example, that includes AV performance metrics for performance of an AV when operated in corresponding real-world and synthetic environments. Further to the examples discussed above with respect to FIG. 1, labeled SIM data 208 can be composed of a combination of determined performance metrics for a real-world scenario (e.g., as determined at block 105) as well as SIM data 108 that has been generated based on road data (e.g., road data 104) that has been received from an AV (e.g., AV 102) operating in a real-world environment.

Using the SIM data, ML model 210 can predict a correspondence between AV performance in an associated simulated environment (e.g., that is represented or defined by the SIM data), as well as a corresponding real-world environment. The resulting predicted performance score correspondence 212 can be represented as a quantitative output on a given interval such as the interval [−1, 1], where 0 can represent a perfect (or near perfect) correspondence, i.e., where AV performance in the SIM environment is almost the same as (or identical to) AV performance in the real-world environment. A score of −1 can indicate that AV performance in the SIM environment was much worse than the AV performance in the real-world environment; a score of 1 can indicate that AV performance in the SIM environment was much better/greater than the AV performance in the real-world. It is understood that other scoring methodologies, or output intervals for ML model 210 may be used, without departing from the scope of the disclosed technology.

One or more weights of ML model 210 can be configured to be updated through a process of error backpropagation, for example, if the predicted correspondence score is different from the ground-truth correspondence score represented in the labeled SIM data 208. As such, ML model 210 can be adapted to variations in SIM data, e.g., to ‘learn’ to identify how different configurations in SIM data can affect the resulting correspondence score. By way of example, labeled SIM data 208 can include information about various topological configurations (e.g., of roadways, intersections, object placements), and interactions between scene entities (e.g., other traffic and non-traffic participants, pedestrians, etc.) that can affect AV performance metrics, as well as their correspondence to corresponding real-world environments. Once trained on a variety of simulated environmental configurations or different SIM training data sets (e.g., environmental topologies, driving scenarios, entity encounters, etc.), ML model 210 may be extended to make predictions about AV performance correspondences for entirely generated simulated environments, for example, that do not have real-world analogues.

FIG. 3 illustrates a conceptual block diagram of an example system 300 for implementing a machine-learning (ML) model to predict an AV performance score correspondence, e.g., between a SIM environment and AV performance in a similar or corresponding real-world environment. Importantly, new SIM data 302 that is provided to ML model 210 need not have corresponding real-world road data. That is, new SIM data 302 can be entirely synthetically generated and not derived or seeded from road-data that is collected from physical AV sensors.

In operation, ML model 210 can make predictions about how an AV would operate in a corresponding real-world environment, for example, that is congruent to (or corresponds with) SIM data 302, e.g., to provide a predicted performance score correspondence 312. As discussed above with respect to FIG. 1 and FIG. 2, the predicted performance score correspondence can be provided on a quantitative interval, such as the interval of [−1, 1], whereby a score of −1 can indicate that AV performance in SIM is predicted to be much lower/worse than AV performance in the corresponding real-world environment; a score of 1 can indicate that AV performance in SIM is predicted to be much greater/better than AV performance in a corresponding real-world environment; and a score of 0 can indicate a perfect (or near perfect) correspondence between AV performance in SIM and AV performance in the real-world. By extending ML model 210 to predicting performance score correspondence for new SIM data 302, entirely synthetic/simulated environments can be evaluated for their fidelity and used in performing AV testing and training. For example, in situations where the performance score correspondence 312 is close to −1 or 1, it can be inferred that the associated simulated environment does not accurately represent real-world scenarios in which the AV may be operated. Similarly, where the performance score correspondence is close to 0, it can be inferred that the simulated environment provides an accurate recreation of the corresponding real-world environment.

FIG. 4 illustrates steps of an example process 400 for training a machine-learning (ML) model to make AV performance predictions. At step 402, process 400 includes generating simulation (SIM) data based on the road data, wherein the SIM data describes a simulated environment based on the real-world environment. The SIM data can be generated (or seeded) from real-world sensor data, such as LiDAR, RADAR, and/or camera data, etc., collected by physical AV sensors. For example, collected sensor data, among other types of metadata, are represented in road data that can be provided to a simulation (SIM) generator (e.g., SIM generator 106) and used to produce SIM data. In some instances, some (or all) of the SIM data may be synthetically generated. For example, for some environmental characteristics, such as atmospheric effects that are not recorded by real-world sensor data, synthetic SIM data may be generated to emulate/replicate the real-world characteristics. By way of example, atmospheric or other weather effects such as fog, rain, and/or hail may be emulated through the generation of synthetic data.

In some aspects, the SIM generator can perform a variety of data preparation and parameterization processes and may include the receipt/generation of other types of data useful for generating a simulated environment (such as atmospheric effects) in which operations of an AV may be simulated. Further details regarding the function of a SIM generator are provided with respect to FIG. 5, below. In some aspects, for model training, multiple sets of simulation data can be generated from multiple different sets of road-data.

At step 404, process 400 includes measuring one or more first performance metrics, wherein the one or more first performance metrics correspond with a performance of the AV in the real-world environment. Measured performance metrics can relate to any of a variety of AV performance characteristics, including but not limited to a safety metric (or safety score), a comfort metric (or comfort score) and/or AV kinematic characteristics, including but not limited to AV trajectory, pose, acceleration, and/or velocity, etc. Additionally, in some implementations, performance metrics can be evaluated for different/specific AV operating domains, for example, performance metrics may be evaluated under different weather conditions, road conditions, AV use cases (e.g., passenger delivery or freight shipping), etc.

At step 406, process 400 includes measuring one or more second performance metrics, wherein the one or more second performance metrics correspond with a performance of the AV in the simulated environment. Performance metrics for the simulated environment can be correspond with the performance metrics measured/determined with respect to AV performance in the real-world environment, including but not limited to metrics for safety, comfort, AV performance, legal or regulatory compliance, and/or metrics relating to AV trajectory and/or kinematics, etc.

At step 408, process 400 includes training a machine-learning (ML) model to predict a correspondence between the performance of the AV in the real-world environment and the performance of the AV in the simulated environment. In some aspects, the ML model can be provided with information relating to a SIM environment, SIM performance metrics for a given SIM environment (e.g., the second performance metrics) and/or performance metrics for AV performance in the real-world environment (e.g., the first performance metrics). Based on the received input information, the ML model can predict a correspondence between AV performance in the SIM environment with respect to AV performance in the real-world environment.

The predicted correspondence score and/or predicted AV performance metrics can be used to calculate a loss function that can be used to update one or more weights of the ML model. For example, if the ML model predicts an output correspondence score of ‘0’ (e.g., indicating perfect correspondence between AV performance in SIM and real-world environments), but the actual correspondence was 0.50, then difference (loss function) can be used to update one or more weights of the ML model. By training the ML model on different real-world/SIM environment examples, the ML model can be trained to predict performance correspondence scores based on different types of input information. For example, the ML model may be trained to predict performance correspondence scores based on road data, SIM environment data, and/or combinations of real-world/SIM environment information and/or AV performance scores for the real-world/SIM environment, etc.

FIG. 5 is a diagram illustrating an example simulation framework 500, according to some examples of the present disclosure. The example simulation framework 500 can include data sources 502, content 512, environmental conditions 528, parameterization 530, and simulator 532. The components in the example simulation framework 500 are merely illustrative examples provided for explanation purposes. In other examples, the simulation framework 500 can include other components that are not shown in FIG. 5 and/or more or less components than shown in FIG. 5.

Data sources 502 can be used to create a simulation. Data sources 502 can include, for example and without limitation, one or more crash databases 504, road sensor data 506, map data 508, and/or synthetic data 510. In other examples, data sources 502 can include more or less sources than shown in FIG. 5 and/or one or more data sources that are not shown in FIG. 5.

Crash databases 504 can include crash data (e.g., data describing crashes and/or associated details) generated by vehicles involved in crashes. Road sensor data 506 can include data collected by one or more sensors (e.g., one or more camera sensors, LIDAR sensors, RADAR sensors, SONAR sensors, IMU sensors, GPS/GNSS receivers, and/or any other sensors) of one or more vehicles while the one or more vehicles drive/navigate one or more real-world environments. Map data 508 can include one or more maps (and, in some cases, associated data) such as, for example and without limitation, one or more high-definition (HD) maps, sensor maps, scene maps, and/or any other maps. In some examples, the one or more HD maps can include roadway information such as, for example, lane widths, location of road signs and traffic lights, directions of travel for each lane, road junction information, speed limit information, etc.

Synthetic data 510 can include virtual assets, objects, and/or elements created for a simulated scene, a virtual scene and/or virtual scene elements, and/or any other synthetic data elements. For example, in some cases, the synthetic data 510 can include one or more virtual vehicles, virtual pedestrians, virtual roads, virtual objects, virtual environments/scenes, virtual signs, virtual backgrounds, virtual buildings, virtual trees, virtual motorcycles/bicycles, virtual obstacles, virtual environmental elements (e.g., weather, lightening, shadows, etc.), virtual surfaces, etc.

In some examples, data from some or all of the data sources 502 can be used to create content 512. Content 512 can include static content and/or dynamic content. For example, the content 512 can include roadway information 514, maneuvers 516, scenarios 518, signage 520, traffic 522, co-simulation 524, and/or data replay 526. The roadway information 514 can include, for example, lane information (e.g., number of lanes, lane widths, directions of travel for each lane, etc.), the location and information of road signs and/or traffic lights, road junction information, speed limit information, road attributes (e.g., surfaces, angles of inclination, curvatures, obstacles, etc.), road topologies, and/or other roadway information. Maneuvers 516 can include any AV maneuvers, and the scenarios 518 can include specific AV behaviors in certain AV scenes/environments. Signage 520 can include signs such as, for example, traffic lights, road signs, billboards, displayed messages on the road, etc. The traffic 522 can include any traffic information such as, for example, traffic density, traffic fluctuations, traffic patterns, traffic activity, delays, positions of traffic, velocities, volumes of vehicles in traffic, geometries or footprints of vehicles, pedestrians, spaces (occupied and/or unoccupied), etc.

The co-simulation 524 can include a distributed modeling and simulation of different AV subsystems that form the larger AV system. In some cases, co-simulation 524 can include information for connecting separate simulations together with interactive communications. In some cases, the co-simulation 524 can allow for modeling to be done at a subsystem level while providing interfaces to connect the subsystems to the rest of the system (e.g., the autonomous driving system computer). Moreover, data replay 526 can include replay content produced from real-world sensor data (e.g., road sensor data 506).

Environmental conditions 528 can include any information about environmental conditions 528. For example, the environmental conditions 528 can include atmospheric conditions, road/terrain conditions (e.g., surface slope or gradient, surface geometry, surface coefficient of friction, road obstacles, etc.), illumination, weather, road and/or scene conditions resulting from one or more environmental conditions, etc.

Content 512 and the environmental conditions 528 can be used to create the parameterization 530. The parameterization 530 can include parameter ranges, parameterized scenarios, probability density functions of one or more parameters, sampled parameter values, parameter spaces to be tested, evaluation windows for evaluating a behavior of an AV in a simulation, scene parameters, content parameters, environmental parameters, etc. The parameterization 530 can be used by a simulator 532 to generate a simulation 540.

Simulator 532 can include a software engine(s), algorithm(s), neural network model(s), and/or software component(s) used to generate simulations, such as simulation 540. In some examples, the simulator 532 can include ADSC/subsystem models 534, sensor models 536, and a vehicle dynamics model 538. The ADSC/subsystem models 534 can include models, descriptors, and/or interfaces for the autonomous driving system computer (ADSC) and/or ADSC subsystems such as, for example, a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

The sensor models 536 can include mathematical representations of hardware sensors and an operation (e.g., sensor data processing) of one or more sensors (e.g., a LIDAR, a RADAR, a SONAR, a camera sensor, an IMU, and/or any other sensor). The vehicle dynamics model 538 can model vehicle behaviors/operations, vehicle attributes, vehicle trajectories, vehicle positions, etc.

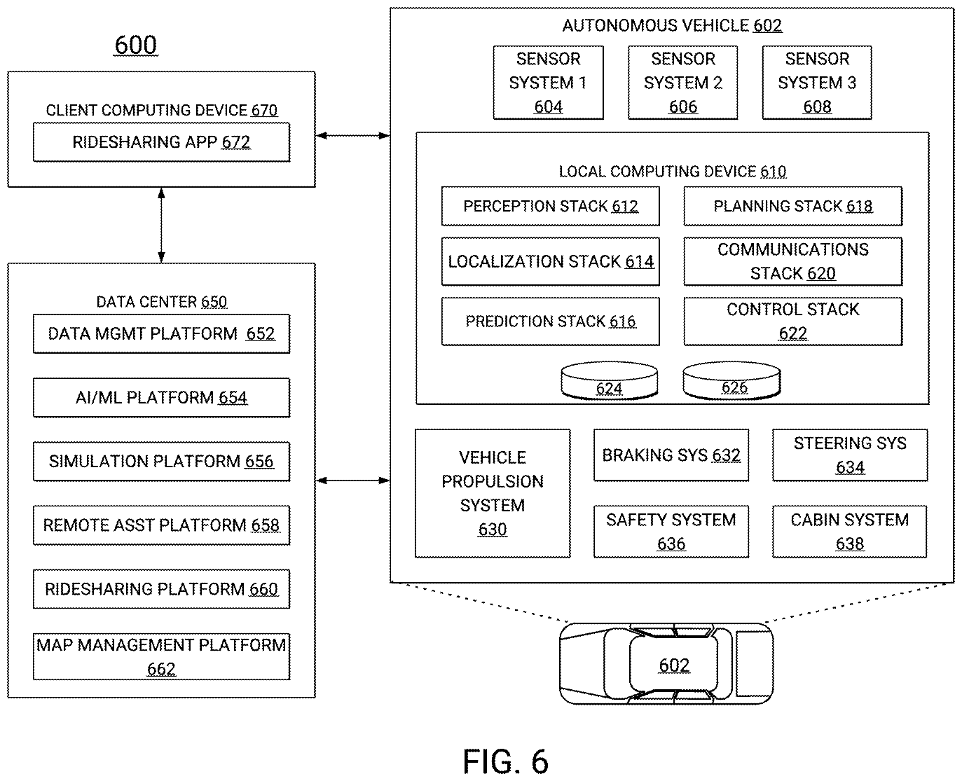

FIG. 6 is a diagram illustrating an example autonomous vehicle (AV) environment 600, according to some examples of the present disclosure. One of ordinary skill in the art will understand that, for the AV environment 600 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment 600 includes an AV 602, a data center 650, and a client computing device 670. The AV 602, the data center 650, and the client computing device 670 can communicate with one another over one or more networks (not shown), such as a public network (e.g., the Internet, an Infrastructure as a Service (IaaS) network, a Platform as a Service (PaaS) network, a Software as a Service (Saas) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 602 can navigate roadways without a human driver based on sensor signals generated by multiple sensor systems 604, 606, and 608. The sensor systems 604-608 can include one or more types of sensors and can be arranged about the AV 602. For instance, the sensor systems 604-608 can include Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 604 can be a camera system, the sensor system 606 can be a LIDAR system, and the sensor system 608 can be a RADAR system. Other examples may include any other number and type of sensors.

The AV 602 can also include several mechanical systems that can be used to maneuver or operate the AV 602. For instance, the mechanical systems can include a vehicle propulsion system 630, a braking system 632, a steering system 634, a safety system 636, and a cabin system 638, among other systems. The vehicle propulsion system 630 can include an electric motor, an internal combustion engine, or both. The braking system 632 can include an engine brake, brake pads, actuators, and/or any other suitable componentry configured to assist in decelerating the AV 602. The steering system 634 can include suitable componentry configured to control the direction of movement of the AV 602 during navigation. The safety system 636 can include lights and signal indicators, a parking brake, airbags, and so forth. The cabin system 638 can include cabin temperature control systems, in-cabin entertainment systems, and so forth. In some examples, the AV 602 might not include human driver actuators (e.g., steering wheel, handbrake, foot brake pedal, foot accelerator pedal, turn signal lever, window wipers, etc.) for controlling the AV 602. Instead, the cabin system 638 can include one or more client interfaces (e.g., Graphical User Interfaces (GUIs), Voice User Interfaces (VUIs), etc.) for controlling certain aspects of the mechanical systems 630-638.

The AV 602 can include a local computing device 610 that is in communication with the sensor systems 604-608, the mechanical systems 630-638, the data center 650, and the client computing device 670, among other systems. The local computing device 610 can include one or more processors and memory, including instructions that can be executed by the processors. The instructions can make up one or more software stacks or components responsible for controlling the AV 602; communicating with the data center 650, the client computing device 670, and other systems; receiving inputs from riders, passengers, and other entities within the AV's environment; logging metrics collected by the sensor systems 604-608; and so forth. In this example, the local computing device 610 includes a perception stack 612, a localization stack 614, a prediction stack 616, a planning stack 618, a communications stack 620, a control stack 622, an AV operational database 624, and an HD geospatial database 626, among other stacks and systems.

The perception stack 612 can enable the AV 602 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 604-608, the localization stack 614, the HD geospatial database 626, other components of the AV, and other data sources (e.g., the data center 650, the client computing device 670, third party data sources, etc.). The perception stack 612 can detect and classify objects and determine their current locations, speeds, directions, and the like. In addition, the perception stack 612 can determine the free space around the AV 602 (e.g., to maintain a safe distance from other objects, change lanes, park the AV, etc.). Perception stack 612 can identify environmental uncertainties, such as where to look for moving objects, flag areas that may be obscured or blocked from view, and so forth. In some examples, an output of the perception stack 612 can be a bounding area around a perceived object that can be associated with a semantic label that identifies the type of object that is within the bounding area, the kinematic of the object (information about its movement), a tracked path of the object, and a description of the pose of the object (its orientation or heading, etc.).

Localization stack 614 can determine the AV's position and orientation (pose) using different methods from multiple systems (e.g., GPS, IMUs, cameras, LIDAR, RADAR, ultrasonic sensors, the HD geospatial database 626, etc.). For example, in some cases, the AV 602 can compare sensor data captured in real-time by the sensor systems 604-608 to data in the HD geospatial database 626 to determine its precise (e.g., accurate to the order of a few centimeters or less) position and orientation. The AV 602 can focus its search based on sensor data from one or more first sensor systems (e.g., GPS) by matching sensor data from one or more second sensor systems (e.g., LIDAR). If the mapping and localization information from one system is unavailable, the AV 602 can use mapping and localization information from a redundant system and/or from remote data sources.

The prediction stack 616 can receive information from the localization stack 614 and objects identified by the perception stack 612 and predict a future path for the objects. In some examples, the prediction stack 616 can output several likely paths that an object is predicted to take along with a probability associated with each path. For each predicted path, the prediction stack 616 can also output a range of points along the path corresponding to a predicted location of the object along the path at future time intervals along with an expected error value for each of the points that indicates a probabilistic deviation from that point.

Planning stack 618 can determine how to maneuver or operate the AV 602 safely and efficiently in its environment. For example, the planning stack 618 can receive the location, speed, and direction of the AV 602, geospatial data, data regarding objects sharing the road with the AV 602 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 602 from one point to another and outputs from the perception stack 612, localization stack 614, and prediction stack 616. The planning stack 618 can determine multiple sets of one or more mechanical operations that the AV 602 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 618 can select from multiple backup plans to carry out. For example, while preparing to change lanes to turn right at an intersection, another vehicle may aggressively cut into the destination lane, making the lane change unsafe. The planning stack 618 could have already determined an alternative plan for such an event. Upon its occurrence, it could help direct the AV 602 to go around the block instead of blocking a current lane while waiting for an opening to change lanes.

The control stack 622 can manage the operation of the vehicle propulsion system 630, the braking system 632, the steering system 634, the safety system 636, and the cabin system 638. The control stack 622 can receive sensor signals from the sensor systems 604-608 as well as communicate with other stacks or components of the local computing device 610 or a remote system (e.g., the data center 650) to effectuate operation of the AV 602. For example, control stack 622 can implement the final path or actions from the multiple paths or actions provided by the planning stack 618. This can involve turning the routes and decisions from planning stack 618 into commands for the actuators that control the AV's steering, throttle, brake, and drive unit.

The communications stack 620 can transmit and receive signals between the various stacks and other components of the AV 602 and between the AV 602, the data center 650, the client computing device 670, and other remote systems. The communications stack 620 can enable the local computing device 610 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 620 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Low Power Wide Area Network (LPWAN), Bluetooth®, infrared, etc.).

The HD geospatial database 626 can store HD maps and related data of the streets upon which the AV 602 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 624 can store raw AV data generated by the sensor systems 604-608, stacks 612-622, and other components of the AV 602 and/or data received by the AV 602 from remote systems (e.g., the data center 650, the client computing device 670, etc.). In some examples, the raw AV data can include HD LIDAR point cloud data, image data, RADAR data, GPS data, and other sensor data that the data center 650 can use for creating or updating AV geospatial data or for creating simulations of situations encountered by AV 602 for future testing or training of various machine learning algorithms that are incorporated in the local computing device 610.

Data center 650 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. Data center 650 can include one or more computing devices remote to the local computing device 610 for managing a fleet of AVs and AV-related services. For example, in addition to managing the AV 602, the data center 650 may also support a ridesharing service, a delivery service, a remote/roadside assistance service, street services (e.g., street mapping, street patrol, street cleaning, street metering, parking reservation, etc.), and the like.

Data center 650 can send and receive various signals to and from the AV 602 and the client computing device 670. These signals can include sensor data captured by the sensor systems 604-608, roadside assistance requests, software updates, ridesharing pick-up and drop-off instructions, and so forth. In this example, the data center 650 includes a data management platform 652, an Artificial Intelligence/Machine Learning (AI/ML) platform 654, a simulation platform 656, a remote assistance platform 658, and a ridesharing platform 660, and a map management platform 662, among other systems.

Data management platform 652 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 650 can access data stored by the data management platform 652 to provide their respective services.

The AI/ML platform 654 can provide the infrastructure for training and evaluating machine learning algorithms for operating the AV 602, the simulation platform 656, the remote assistance platform 658, the ridesharing platform 660, the map management platform 662, and other platforms and systems. Using the AI/ML platform 654, data scientists can prepare data sets from the data management platform 652; select, design, and train machine learning models; evaluate, refine, and deploy the models; maintain, monitor, and retrain the models; and so on.

Simulation platform 656 can enable testing and validation of the algorithms, machine learning models, neural networks, and other development efforts for the AV 602, the remote assistance platform 658, ridesharing platform 660, map management platform 662, and other platforms and systems. Simulation platform 656 can replicate a variety of driving environments and/or reproduce real-world scenarios from data captured by the AV 602, including rendering geospatial information and road infrastructure (e.g., streets, lanes, crosswalks, traffic lights, stop signs, etc.) obtained from a cartography platform (e.g., map management platform 662); modeling the behavior of other vehicles, bicycles, pedestrians, and other dynamic elements; simulating inclement weather conditions, different traffic scenarios; and so on.

Rremote assistance platform 658 can generate and transmit instructions regarding the operation of the AV 602. For example, in response to an output of the AI/ML platform 654 or other system of the data center 650, remote assistance platform 658 can prepare instructions for one or more stacks or other components of the AV 602.

Ridesharing platform 660 can interact with a customer of a ridesharing service via a ridesharing application 672 executing on the client computing device 670. The client computing device 670 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 672. Cclient computing device 670 can be a customer's mobile computing device or a computing device integrated with the AV 602 (e.g., the local computing device 610). The ridesharing platform 660 can receive requests to pick up or drop off from the ridesharing application 672 and dispatch the AV 602 for the trip.

Map management platform 662 can provide a set of tools for the manipulation and management of geographic and spatial (geospatial) and related attribute data. The data management platform 652 can receive LIDAR point cloud data, image data (e.g., still image, video, etc.), RADAR data, GPS data, and other sensor data (e.g., raw data) from one or more AVs 602, Unmanned Aerial Vehicles (UAVs), satellites, third-party mapping services, and other sources of geospatially referenced data. The raw data can be processed, and map management platform 662 can render base representations (e.g., tiles (2D), bounding volumes (3D), etc.) of the AV geospatial data to enable users to view, query, label, edit, and otherwise interact with the data. Map management platform 662 can manage workflows and tasks for operating on the AV geospatial data. Map management platform 662 can control access to the AV geospatial data, including granting or limiting access to the AV geospatial data based on user-based, role-based, group-based, task-based, and other attribute-based access control mechanisms. Map management platform 662 can provide version control for the AV geospatial data, such as tracking specific changes that (human or machine) map editors have made to the data and to revert changes when necessary. Map management platform 662 can administer release management of the AV geospatial data, including distributing suitable iterations of the data to different users, computing devices, AVs, and other consumers of HD maps. Map management platform 662 can provide analytics regarding the AV geospatial data and related data, such as to generate insights relating to the throughput and quality of mapping tasks.

In some embodiments, the map viewing services of map management platform 662 can be modularized and deployed as part of one or more of the platforms and systems of the data center 650. For example, AI/ML platform 654 may incorporate the map viewing services for visualizing the effectiveness of various object detection or object classification models, the simulation platform 656 may incorporate the map viewing services for recreating and visualizing certain driving scenarios, the remote assistance platform 658 may incorporate the map viewing services for replaying traffic incidents to facilitate and coordinate aid, the ridesharing platform 660 may incorporate the map viewing services into the client application 672 to enable passengers to view the AV 602 in transit en route to a pick-up or drop-off location, and so on.

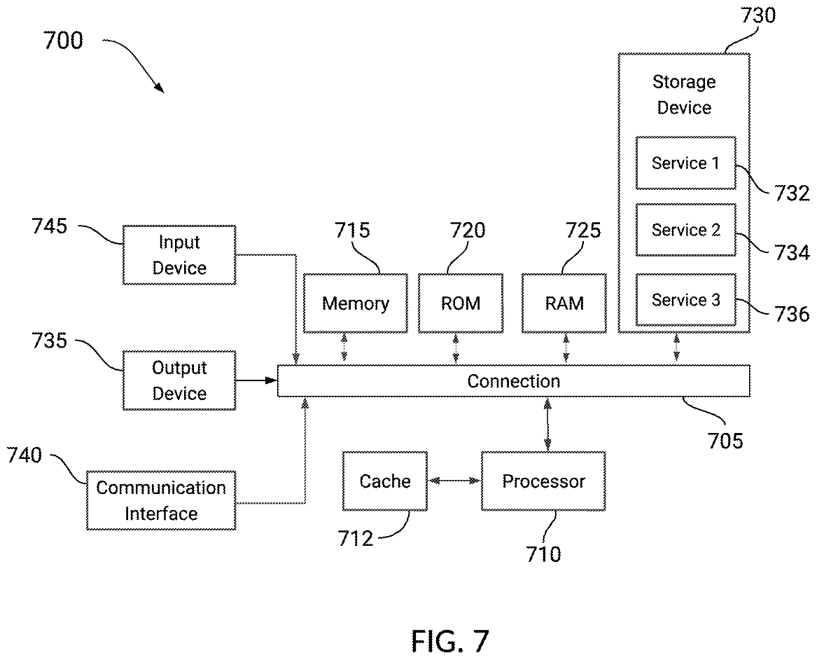

While the autonomous vehicle 602, the local computing device 610, and the autonomous vehicle environment 600 are shown to include certain systems and components, one of ordinary skill will appreciate that the autonomous vehicle 602, the local computing device 610, and/or the autonomous vehicle environment 600 can include more or fewer systems and/or components than those shown in FIG. 6. For example, the autonomous vehicle 602 can include other services than those shown in FIG. 6 and the local computing device 610 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 6. An illustrative example of a computing device and hardware components that can be implemented with the local computing device 610 is described below with respect to FIG. 7.

FIG. 7 illustrates an example processor-based system with which some aspects of the subject technology can be implemented. For example, processor-based system 700 can be any computing device making up, or any component thereof in which the components of the system are in communication with each other using connection 705. Connection 705 can be a physical connection via a bus, or a direct connection into processor 710, such as in a chipset architecture. Connection 705 can also be a virtual connection, networked connection, or logical connection.

In some embodiments, computing system 700 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 700 includes at least one processing unit (Central Processing Unit (CPU) or processor) 710 and connection 705 that couples various system components including system memory 715, such as Read-Only Memory (ROM) 720 and Random-Access Memory (RAM) 725 to processor 710. Computing system 700 can include a cache of high-speed memory 712 connected directly with, in close proximity to, or integrated as part of processor 710.

Processor 710 can include any general-purpose processor and a hardware service or software service, such as services 732, 734, and 736 stored in storage device 730, configured to control processor 710 as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction, computing system 700 includes an input device 745, which can represent any number of input mechanisms, such as a microphone for speech, a touch-sensitive screen for gesture or graphical input, keyboard, mouse, motion input, speech, etc. Computing system 700 can also include output device 735, which can be one or more of a number of output mechanisms known to those of skill in the art. In some instances, multimodal systems can enable a user to provide multiple types of input/output to communicate with computing system 700. Computing system 700 can include communications interface 740, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 740 may also include one or more Global Navigation Satellite System (GNSS) receivers or transceivers that are used to determine a location of the computing system 700 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 730 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L #), Resistive RAM (RRAM/ReRAM), Phase Change Memory (PCM), Spin Transfer Torque RAM (STT-RAM), another memory chip or cartridge, and/or a combination thereof.

Storage device 730 can include software services, servers, services, etc., when the code that defines such software is executed by the processor 710, it causes the system 700 to perform a function. In some embodiments, a hardware service that performs a particular function can include the software component stored in a computer-readable medium in connection with the necessary hardware components, such as processor 710, connection 705, output device 735, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

Illustrative aspects of the disclosure include:

Aspect 1: An apparatus comprising: at least one memory; and at least one processor coupled to the at least one memory, the at least one processor configured to: receive road data comprising autonomous vehicle (AV) sensor data collected for a real-world environment navigated by an AV; generate simulation (SIM) data based on the road data, wherein the SIM data describes a simulated environment based on the real-world environment; measure one or more first performance metrics, wherein the one or more first performance metrics correspond with a performance of the AV in the real-world environment; measure one or more second performance metrics, wherein the one or more second performance metrics correspond with a performance of the AV in the simulated environment; and train a machine-learning (ML) model to predict a correspondence between the performance of the AV in the real-world environment and the performance of the AV in the simulated environment.

Aspect 2: The apparatus of aspect 1, wherein to train the ML model, the at least one processor is configured to: calculate a loss function based on a difference between the one or more first performance metrics and the one or more second performance metrics; and update one or more weights of the ML model based on the loss function.

Aspect 3: The apparatus of any of aspects 1-2, wherein the at least one processor is further configured to: provide new SIM data to the ML model; and receive, from the ML model, a prediction regarding how an AV would perform in a new simulated environment based on the new SIM data.

Aspect 4: The apparatus of aspects 1-3, wherein the new SIM data is not derived from AV sensor data.

Aspect 5: The apparatus of aspects 1-4, wherein the ML model is a regressor, a random forest, a convolutional neural network (CNN), or a combination thereof.

Aspect 6: The apparatus of aspects 1-5, wherein to generate the SIM data, the at least one processor is further configured to: generate one or more atmospheric effects for rendering in the simulated environment.

Aspect 7: The apparatus of aspects 1-6, wherein the AV sensor data comprises Light Detection and Ranging (LiDAR) data, Radio Detection and Ranging (RADAR) data, camera data, or a combination thereof.

Aspect 8: A computer-implemented method comprising: receiving road data comprising autonomous vehicle (AV) sensor data collected for a real-world environment navigated by an AV; generating simulation (SIM) data based on the road data, wherein the SIM data describes a simulated environment based on the real-world environment; measuring one or more first performance metrics, wherein the one or more first performance metrics correspond with a performance of the AV in the real-world environment; measuring one or more second performance metrics, wherein the one or more second performance metrics correspond with a performance of the AV in the simulated environment; and training a machine-learning (ML) model to predict a correspondence between the performance of the AV in the real-world environment and the performance of the AV in the simulated environment.

Aspect 9: The computer-implemented method of aspect 8, wherein training the ML model further comprises: calculating a loss function based on a difference between the one or more first performance metrics and the one or more second performance metrics; and updating one or more weights of the ML model based on the loss function.

Aspect 10: The computer-implemented method of any of aspects 8-9, further comprising: providing new SIM data to the ML model; and receiving, from the ML model, a prediction regarding how an AV would perform in a new simulated environment based on the new SIM data.

Aspect 11: The computer-implemented method of aspects 8-10, wherein the new SIM data is not derived from AV sensor data.

Aspect 12: The computer-implemented method of aspects 8-11, wherein the ML model is a regressor, a random forest, a convolutional neural network (CNN), or a combination thereof.

Aspect 13: The computer-implemented method of aspects 8-12, generating the SIM data further comprises: generating one or more atmospheric effects for rendering in the simulated environment.

Aspect 14: The computer-implemented method of aspects 8-13, wherein the AV sensor data comprises Light Detection and Ranging (LiDAR) data, Radio Detection and Ranging (RADAR) data, camera data, or a combination thereof.

Aspect 15: A non-transitory computer-readable storage medium comprising at least one instruction for causing a computer or processor to: receive road data comprising autonomous vehicle (AV) sensor data collected for a real-world environment navigated by an AV; generate simulation (SIM) data based on the road data, wherein the SIM data describes a simulated environment based on the real-world environment; measure one or more first performance metrics, wherein the one or more first performance metrics correspond with a performance of the AV in the real-world environment; measure one or more second performance metrics, wherein the one or more second performance metrics correspond with a performance of the AV in the simulated environment; and train a machine-learning (ML) model to predict a correspondence between the performance of the AV in the real-world environment and the performance of the AV in the simulated environment.

Aspect 16: The non-transitory computer-readable storage medium of aspect 15, wherein to train the ML model, the at least one instruction is further configured to cause the computer or processor to: calculate a loss function based on a difference between the one or more first performance metrics and the one or more second performance metrics; and update one or more weights of the ML model based on the loss function.

Aspect 17: The non-transitory computer-readable storage medium of any of aspects 15-16, wherein the at least one instruction is configured to cause the computer or processor to: provide new SIM data to the ML model; and receive, from the ML model, a prediction regarding how an AV would perform in a new simulated environment based on the new SIM data.

Aspect 18: The non-transitory computer-readable storage medium of aspects 15-17, wherein the new SIM data is not derived from AV sensor data.

Aspect 19: The non-transitory computer-readable storage medium of aspects 15-18, wherein the ML model is a regressor, a random forest, a convolutional neural network (CNN), or a combination thereof.

Aspect 20: The non-transitory computer-readable storage medium of aspects 15-19, wherein to generate the SIM data, the at least one processor is further configured to: generate one or more atmospheric effects for rendering in the simulated environment.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. An apparatus comprising:
at least one memory; and
at least one processor coupled to the at least one memory, the at least one processor configured to:
receive road data comprising autonomous vehicle (AV) sensor data collected for a real-world environment navigated by an AV;
generate simulation (SIM) data based on the road data, wherein the SIM data describes a simulated environment based on the real-world environment;
measure one or more first performance metrics, wherein the one or more first performance metrics correspond with a performance of the AV in the real-world environment;
measure one or more second performance metrics, wherein the one or more second performance metrics correspond with a performance of the AV in the simulated environment; and
train a machine-learning (ML) model to predict a correspondence between the performance of the AV in the real-world environment and the performance of the AV in the simulated environment.

2. The apparatus of claim 1, wherein to train the ML model, the at least one processor is configured to:
calculate a loss function based on a difference between the one or more first performance metrics and the one or more second performance metrics; and
update one or more weights of the ML model based on the loss function.

3. The apparatus of claim 1, wherein the at least one processor is further configured to:
provide new SIM data to the ML model; and
receive, from the ML model, a prediction regarding how an AV would perform in a new simulated environment based on the new SIM data.

4. The apparatus of claim 3, wherein the new SIM data is not derived from AV sensor data.

5. The apparatus of claim 1, wherein the ML model is a regressor, a random forest, a convolutional neural network (CNN), or a combination thereof.

6. The apparatus of claim 1, wherein to generate the SIM data, the at least one processor is further configured to:
generate one or more atmospheric effects for rendering in the simulated environment.

7. The apparatus of claim 1, wherein the AV sensor data comprises Light Detection and Ranging (LiDAR) data, Radio Detection and Ranging (RADAR) data, camera data, or a combination thereof.

8. A computer-implemented method comprising:
receiving road data comprising autonomous vehicle (AV) sensor data collected for a real-world environment navigated by an AV;
generating simulation (SIM) data based on the road data, wherein the SIM data describes a simulated environment based on the real-world environment;
measuring one or more first performance metrics, wherein the one or more first performance metrics correspond with a performance of the AV in the real-world environment;
measuring one or more second performance metrics, wherein the one or more second performance metrics correspond with a performance of the AV in the simulated environment; and
training a machine-learning (ML) model to predict a correspondence between the performance of the AV in the real-world environment and the performance of the AV in the simulated environment.

9. The computer-implemented method of claim 8, wherein training the ML model further comprises:
calculating a loss function based on a difference between the one or more first performance metrics and the one or more second performance metrics; and
updating one or more weights of the ML model based on the loss function.

10. The computer-implemented method of claim 8, further comprising:
providing new SIM data to the ML model; and
receiving, from the ML model, a prediction regarding how an AV would perform in a new simulated environment based on the new SIM data.

11. The computer-implemented method of claim 10, wherein the new SIM data is not derived from AV sensor data.

12. The computer-implemented method of claim 8, wherein the ML model is a regressor, a random forest, a convolutional neural network (CNN), or a combination thereof.

13. The computer-implemented method of claim 8, generating the SIM data further comprises:
generating one or more atmospheric effects for rendering in the simulated environment.

14. The computer-implemented method of claim 8, wherein the AV sensor data comprises Light Detection and Ranging (LiDAR) data, Radio Detection and Ranging (RADAR) data, camera data, or a combination thereof.

15. A non-transitory computer-readable storage medium comprising at least one instruction for causing a computer or processor to:
receive road data comprising autonomous vehicle (AV) sensor data collected for a real-world environment navigated by an AV;
generate simulation (SIM) data based on the road data, wherein the SIM data describes a simulated environment based on the real-world environment;
measure one or more first performance metrics, wherein the one or more first performance metrics correspond with a performance of the AV in the real-world environment;
measure one or more second performance metrics, wherein the one or more second performance metrics correspond with a performance of the AV in the simulated environment; and
train a machine-learning (ML) model to predict a correspondence between the performance of the AV in the real-world environment and the performance of the AV in the simulated environment.

16. The non-transitory computer-readable storage medium of claim 15, wherein to train the ML model, the at least one instruction is further configured to cause the computer or processor to:
calculate a loss function based on a difference between the one or more first performance metrics and the one or more second performance metrics; and
update one or more weights of the ML model based on the loss function.

17. The non-transitory computer-readable storage medium of claim 15, wherein the at least one instruction is configured to cause the computer or processor to:
provide new SIM data to the ML model; and
receive, from the ML model, a prediction regarding how an AV would perform in a new simulated environment based on the new SIM data.

18. The non-transitory computer-readable storage medium of claim 17, wherein the new SIM data is not derived from AV sensor data.

19. The non-transitory computer-readable storage medium of claim 15, wherein the ML model is a regressor, a random forest, a convolutional neural network (CNN), or a combination thereof.

20. The non-transitory computer-readable storage medium of claim 15, wherein to generate the SIM data, the at least one processor is further configured to:
generate one or more atmospheric effects for rendering in the simulated environment.
